(19) United States
(12) Patent Application Publication
(10) Pub. No.: US 2001/0003368 A1
(43) Pub. Date: Jun. 14, 2001

(54) OPEN DRAIN INPUT/OUTPUT STRUCTURE AND MANUFACTURING METHOD THEREOF IN SEMICONDUCTOR DEVICE

(76) Inventors: BYUNG-SUP SHIM, SEOUL (KR); YOUNG-HO KIM, KYUNGKI-DO (KR)

Correspondence Address: MARGER JOHNSON & MCCOLLOM P C, 1030 S W MORRISON STREET, PORTLAND, OR, 97205

(21) Appl. No.: 09/305,240

(22) Filed: May 4, 1999

(30) Foreign Application Priority Data
May 4, 1998 (KR) 98-15975

(51) Int. Cl. H01L 29/76; H01L 29/94

(52) U.S. Cl. 257/391

(57) ABSTRACT

An improved pull-up transistor is provided for use as an open drain input/output structure. The transistor includes a source and a drain that define a channel between them. An impurity implantation region in the channel does not reach both the source and the drain. The impurity can reach only the source, only the drain, or none of them. As such, it presents a discontinuity, which serves as a p-type channel. The transistor therefore can act as an enhancement transistor used for pull-up. The invention can be implemented with a mask ROM embedded MCU, or an EPROM embedded MCU.

### BACKGROUND OF THE INVENTION

1. Field of the Invention

The present invention relates to a semiconductor device and manufacturing method thereof, and more particularly to an open drain input/output structure and manufacturing method.

2. Description of the Prior Art

In general, when an input/output (I/O) of a MASKROM embedded MCU is implemented, it is necessary to establish a single layout for an open drain option and for a pull-up option. Accordingly, when devices in the MASKROM embedded MCU are manufactured, two I/Os (open drain I/O and pull-up I/O) are typically implemented as transistors, and more particularly as follows.

A pull-up I/O is first formed in such a manner that a contrary type of impurity to a substrate is ion-implanted into the channel region so that a gate is formed. Thereafter an open drain I/O is formed by starting with what would be a depletion transistor, and converting it into an enhancement transistor by further ion-implanting an impurity of the same type as the substrate into only a specific region. The specific region is the channel region of a cell which would be used as an open drain option during after gate programming (AGP) process.

The selective change of the depletion transistor into the enhancement transistor is for cutting off the depletion transistor for a pull-up resistance by the impurity ion implantation process (because a current flow occurs through the pull-up resistance, thereby causing an external component not to be controlled, when the both terminals of the pull-up resistance of the pull-up resistance type I/O are applied with an electric voltage source of a chip and an external high voltage). Here, the open drain I/O controls components by using an external high voltage.

That is, the depletion transistor is used as the pull-up resistance on the condition that the depletion transistor is changed into the enhancement transistor by the impurity ion implantation process for a channel region after being patterned a gate when the depletion transistor is intended to use as the open drain I/O.

FIG. 1 shows a circuit corresponding to a conventional open drain I/O structure. Reference numeral C represents a cutting-off node of the open drain circuit, D an open drain I/O input terminal, E an external component and Vdd an internal voltage terminal.

Two transistors A, B are respectively connected to a second and first internal logic circuits 10b and 10a. Transistor A is a n-channel open drain transistor. Transistor B is a pull-up or enhancement transistor, which has been so made by changing an n-channel depletion transistor by ion implanting impurities, after the gate is formed. The two transistors are connected in series each other through cutoff node C, which in turn is connected to an input/output pad 20. The pad 20 is connected with an external analog IC for applying an external high voltage unlike MOS-type LSI.

Pull-up transistor B is connected between a Vdd terminal and a pad 20 by the source and the drain. Because it should be maintained in the cut-off state, the first internal logic circuit 10a should be established to output a low level signal. When the second internal logic circuit 10b keeps a high level, an external signal is applied through the pad 20, and then a current flows through the open drain transistor A, so as to operate the external component.

FIG. 2 shows a conventional structure of a n-channel open drain transistor A. A gate insulating layer 34 is formed on an active region of a p-type semiconductor substrate 30 which is formed with a field oxide film 32.

A gate 26 is formed on a predetermined portion of the gate insulating layer 34. The gate is preferably formed with a layer of a W-silicide 26b accumulated on a polysilicon layer 26a.

An insulative spacer 28 is formed on each side wall of the gate 26. N-type source and drain regions 42a and 42b are formed in substrate 30, provided with LDD (lightly doped drain) regions 40. A channel region is defined between them.

Referring to FIGS. 3 and 4, an enhancement transistor B is shown. It has a very similar structure to transistor A of FIG. 2, except for the following. The gate is numbered 36, is comprised of respective layers 36a, 36b, and its line width is W2. Spacers 38 are formed around it.

Further, at the channel region under gate 36, a n-type impurity implantation region 44 is formed. It is over a region that is adjacent to or even overlaps both the source and drain, and thus forms a continuous path of a n-type impurity between them.

Additionally, a p-type impurity implantation region 46 is further formed at a middle section of region 44. The p-type impurity implantation region serves as the pull-up resistance after the gate is formed. This ensures that a constant off state is kept, except when the gate is provided with a high level signal.

The conventional method for forming the open drain I/O has the following drawbacks: First, in transistor B, the additional impurity ion implantation process must be performed one more time for forming the p-type impurity implantation region 46, after the gate is formed. This causes not only the process to be complicated, but also cost to be increased.

Second, when a system maker intends to achieve a EPROM embedded MCU by using a non-volatile memory (for example EPROM for the purpose of developing a program and for applying to the market), there is no problem to achieve the open drain I/O by the process and the layout different from a conventional mask ROM embedded MCU. However, there is a problem for the open drain I/O to achieve by using the same layout as the conventional layout. That is, since an AGP (after gate programming) coding is not used for the EPROM embedded MCU, it is not necessary the impurity ion implantation process after the gate is formed. Therefore, it is not possible to achieve selectively between the I/O for the pull-up resistance of the EPROM embedded MCU and the open drain I/O. That is, it is possible for the mask ROM embedded MCU to achieve the open drain I/O and the I/O for pull-up resistance, but it is possible for the EPROM embedded MCU to achieve only the I/O for pull-up resistance.

Therefore, it is required for the open drain I/O having the same layout to apply in the mask ROM embedded MCU and the EPROM embedded MCU.

### SUMMARY OF THE INVENTION

The present invention overcomes these problems of the prior art. The invention provides an improved pull-up transistor that is to be used in place of the enhancement transistor B of the prior art. The transistor includes a source and a drain that can be connected to a Vdd terminal and to an I/O pad. In the channel of the transistor there is an impurity implantation region that does not reach both the source and the drain. In other words, it presents a discontinuity, which serves as a p-type channel. This avoids the need of the prior art for the additional p-type ion-implantation process, after forming the gate.

According to the first embodiment, the impurity reaches the source, but not the drain. In the second embodiment, the impurity reaches the drain, but not the source. In the third embodiment the impurity reaches neither the source nor the drain, thus presenting at least two discontinuities. The invention can be implemented with a mask ROM embedded MCU, an EPROM embedded MCU.

Another object of the present invention is to provide an open drain input/output transistor manufacturing method, which enables to effectively achieve an open drain structure of the input/output.

The invention also provides a method of manufacture of the device. A gate insulating layer is formed in an active region on a p-type semiconductor substrate; then an impurity implantation region is formed at a predetermined first sector within the substrate by ion-implanting a n-type impurity. Then a gate is formed on the gate insulating layer over at least a portion of the first sector and over a region adjacent to the first sector. Source and drain regions are then formed within the substrate at opposite sides of the gate, by ion-implanting an impurity of the second conductive type. The first sector having been predetermined such that it does not reach both the source region and the drain region.

As a result, using the open drain I/O of the invention enables implementing a MASKROM embedded MCU, I/O for pull-up resistance of EPROM embedded MCU, and open drain I/O with a single lay out structure, which makes it compatible for manufacture with MCU, and more economical.

### BRIEF DESCRIPTION OF THE DRAWINGS

The above object, and other features and advantages of the present invention will become apparent after a reading of the following detailed description when taken in conjunction with the drawings, in which:

FIG. 1 is a schematic circuit diagram illustrating an open drain input/output stage structure of a conventional semiconductor device;

FIG. 2 is a sectional view of open drain transistor A in FIG. 1;

FIG. 3 is a sectional view of pull-up transistor B in FIG. 1;

FIG. 4 is a plan view illustrating the layout structure after the gate is formed in the transistor of FIG. 3;

FIGS. 5a to FIG. 5c are views illustrating an input/output stage structure of a semiconductor device made according to the first embodiment of the present invention, and more specifically:

FIG. 5a is a sectional view illustrating the enhancement transistor structure of the open drain input/output stage,

FIG. 5b is a plan view illustrating the layout structure after the gate is formed, and

FIG. 5c is an equivalent circuit of FIG. 5a;

FIG. 6a to FIG. 6c are views illustrating an input/output stage structure of a semiconductor device made according to the second embodiment of the present invention, and more specifically:

FIG. 6a is a sectional view illustrating the enhancement transistor structure of the open drain input/output stage,

FIG. 6b is a plan view illustrating the layout structure after the gate is formed, and

FIG. 6c is an equivalent circuit of FIG. 6a;

FIG. 7a to FIG. 7c are views illustrating an input/output stage structure of a semiconductor device made according to the third embodiment of the present invention, and more specifically:

FIG. 7a is a sectional view illustrating the enhancement transistor structure of the open drain input/output stage,

FIG. 7b is a plan view illustrating the layout structure after the gate is formed, and

FIG. 7c is an equivalent circuit of FIG. 7a.

### DETAILED DESCRIPTION OF THE PREFERRED EMBODIMENTS

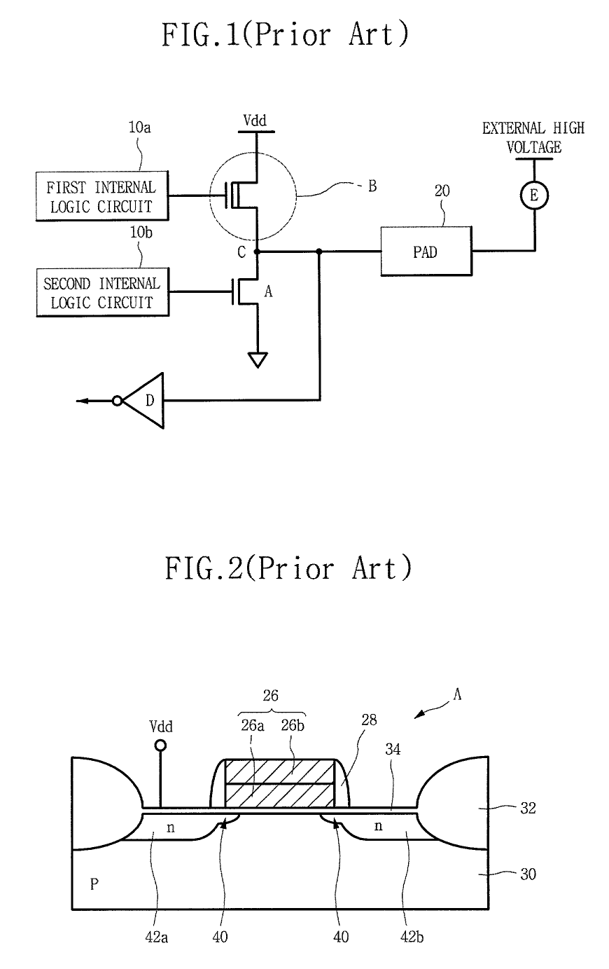

As has been mentioned, the present invention is directed to an improved pull-up transistor that is to be used in place of the enhancement transistor B of FIG. 1 of the prior art. The transistor includes a source and a drain that can be connected to a Vdd terminal and to an I/O pad. In the channel of the transistor there is an impurity implantation region that does not reach both the source and the drain.

In the following description, the line width F of the active region becomes important, along with the line widths of the impurity implantation region and of the gate. But for the special impurity implantation region, the transistor would be a n-channel open drain transistor, whose separate description is thus omitted.

### Embodiment 1

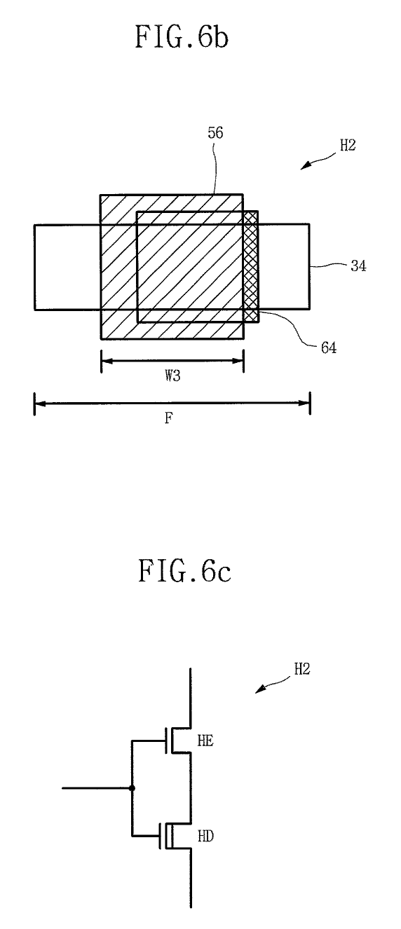

The first embodiment H1 is now described with reference to FIGS. 5a, 5b and 5c. As shown in FIG. 5a, a gate insulating layer 34 with a field oxide layer 32 is formed at an active region of a p-type semiconductor substrate 30. N-type source and drain regions 42a and 42b are formed, defining between them a channel region. They are optionally provided with LDD regions 40.

A n-type impurity implantation region 54 is formed at a first sector of the channel region. While it is coupled to source region 42a, but maintains a predetermined distance -o- from drain region 42b, which is different than in the prior art.

A gate 56 is formed on the gate insulating layer 34. What is further different is that gate 56 is formed on a predetermined portion of the gate insulating layer. Specifically, W3 indicates the line width of gate 56, and F indicates the line width of the active region. The gate is formed over a first portion of the first sector and over a portion of the area adjacent the first sector.

The gate is formed by accumulating a polysilicon layer 56a and a W-silicide (W-silicide/polysilicon) layer 56b. Other embodiments are possible, such as a one step polysilicon layer. Then both side walls are formed with an insulating spacer 58.

The enhancement transistor H1 having the above-structure is manufactured through the following four steps.

As a first step, the gate insulating layer 34 is formed at the active region on the p-type semiconductor substrate 30, which is formed with the field oxide layer 32. Then an n-type impurity is selectively implanted on a selected portion of the gate insulating layer 34. Accordingly, an n-type impurity implantation region 54 is formed at the portions in the substrate 30, which are collectively known as the first sector of the substrate.

As a second step, the gate 56 is formed on the gate insulating layer 34. The gate is over a first portion of the first sector, i.e. over at least some of the impurity implantation region 54. The gate is also over a second portion of the surface of the substrate 30 that is adjacent region 54. The gate can be manufactured by depositing a conductive layer and then selectively etching it to conform to the desired shape.

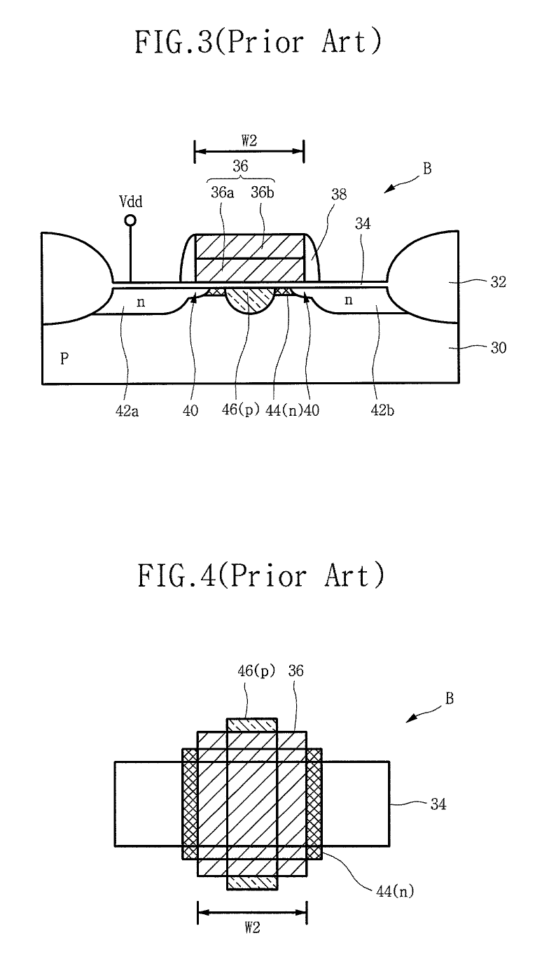

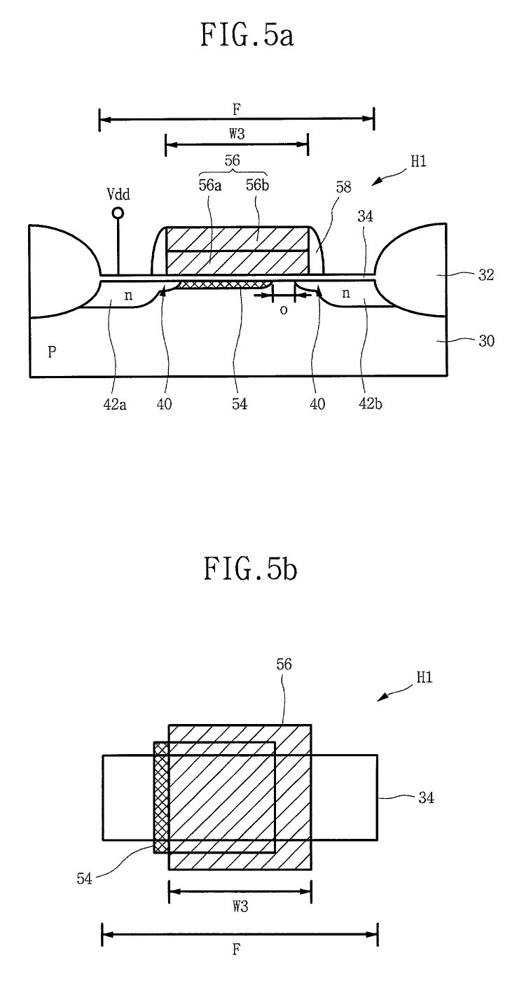

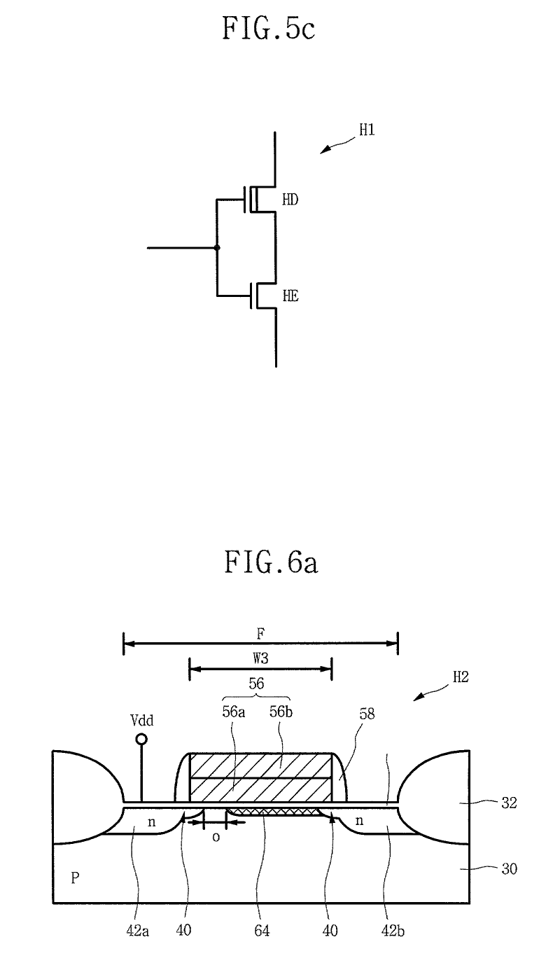

Because the n-type impurity implantation region 54 should be formed only at the certain portions of the channel region in order to achieve the open drain structure without the p-type impurity ion implantation process for opening the channel, the gate 56 should be formed to have a little longer length W3 than the conventional length W2 of FIG. 2. This is best seen with reference to FIG. 5b.

As a third step, the n-type impurity in low concentration is ion-implanted to the substrate 30 through the gate 56, as a mask so as to form LDD regions 40 in the substrate 30 at both sides of the gate.

As a fourth step, insulating spacers 58 are formed at both side walls of the gate 56. Then the n-type impurity in high concentration is ion-implanted to the substrate 30, using the gate and the spacer 38 as a mask, so as to form the source/drain regions 42a and 42b in the substrate 30.

FIG. 5c illustrates the operation of transistor H1. Transistor H1 operates as a depletion transistor HD in the first sector, which is where the n-channel region includes the n-type impurity implantation region 54. However, it operates as an enhancement transistor HE at the region adjacent the first sector, i.e. the p-channel region (portion “O” in drawing) where the channel lacks the impurity implantation region 54. Accordingly, the enhancement transistor can be cut-off only when a voltage Vdd is applied to the source region, and a low level signal is applied to the gate.

### Embodiment 2

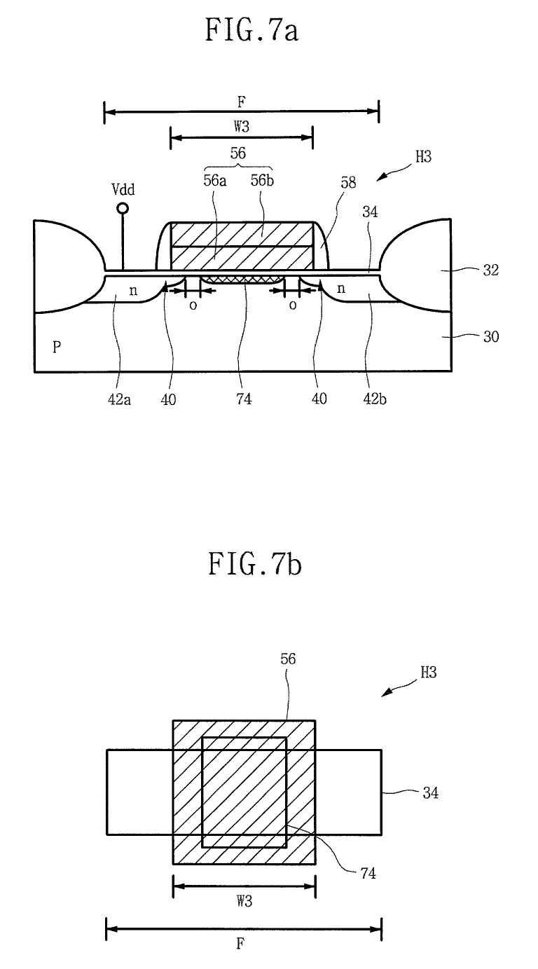

The second embodiment H2 is now described with reference to FIG. 6a, 6b and 6c. It is the same as the first embodiment, except that the first sector reaches the drain region instead of the source region. In other words, a n-type impurity implantation region 64 is formed contiguously to, or overlapping with the drain region, but maintains a predetermined distance -o- from a source region.

FIG. 6c shows an equivalent circuit for transistor H2 of FIG. 6a. Transistor H2 operates similarly to transistor H1 of FIG. 5c.

### Embodiment 3

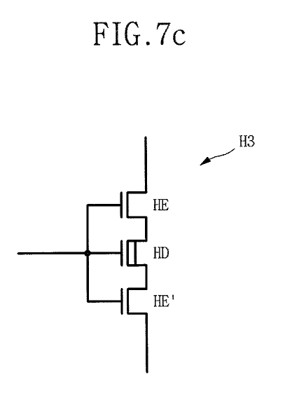

The third embodiment H3 is now described with reference to FIG. 7a, 7b and 7c. It is the same as the first two embodiments, except that the first sector does not reach either one of the source and drain regions. More specifically, a n-type impurity implantation region 74 is formed at predetermined distances from source/drain regions 42a, 42b. Preferably the predetermined distances are equal.

The enhancement transistor having the above-structure is manufactured through substantially the same steps, taking care that the n-type impurity implantation region 74 is formed at portions of the substrate that do not overlap or even contact the source and drain. Further, the gate 56 is formed on the gate insulating layer 34 so as to be over a first portion of the first sector and over a second portion of the surface of the substrate 30 adjacent the first sector. Preferably the first portion is in a predetermined ratio with the second portion.

FIG. 7c shows an equivalent circuit for the transistor in FIG. 7a. P-channels (parts “o” in the drawing) are formed at both sides of the n-channel region, adjacent to the impurity implantation region 44. Transistor H3 having the above structure operates at the p-channel regions as enhancement transistors HE, HE′, and operates at the n-channel regions as depletion transistor HD. Therefore, transistors HE, HE′ can be cut off only when a low level signal is applied to the gate, with the voltage Vdd being applied to the source region.

A person skilled in the art will be able to practice the present invention in view of the present description, where numerous details have been set forth in order to provide a more thorough understanding of the invention. In other instances, well-known features have not been described in detail in order not to obscure unnecessarily the invention.

Having illustrated and described the principles of the invention in its preferred embodiments, it should be readily apparent to those skilled in the art that the invention can be modified in arrangement and detail without departing from such principles. For example, the conductivity types (p-type and n-type, also collectively known as conductive types) can be interchanged. All modifications coming within the spirit and scope of the accompanying claims are claimed as follows.

What is claimed is:

1. A method of manufacturing a pull-up transistor for use with a Vdd terminal and an I/O pad of a semiconductor device comprising:
forming a gate insulating layer in an active region on a first conductive-type semiconductor substrate;
forming an impurity implantation region at a predetermined first sector within the substrate by ion-implanting an impurity of a second conductive-type;
forming a gate on the gate insulating layer over at least a portion of the first sector and over a region adjacent to the first sector;
forming source and drain regions within the substrate at opposite sides of the gate by ion-implanting an impurity of the second conductive type, the first sector having been predetermined such that the impurity implantation region does not reach both the source region and the drain region;
coupling one of the source region and the drain region to the I/O pad; and
coupling the other one of the source region and the drain region to the Vdd terminal.

2. The method of claim 1, wherein the gate is formed by depositing a conductive layer and then selectively etching it.

3. The method of claim 1, wherein forming the impurity implantation region is by ion-implanting at a low concentration.

4. The method of claim 1, further comprising:
forming LDD regions at both sides of the gate; and
forming a spacer adjacent the gate before forming the source and drain regions.

5. A pull-up transistor for use with a Vdd terminal and an I/O pad of a semiconductor device comprising:
a semiconductor substrate of a first conductive-type;
a source region and a drain region of a second conductive type formed in the substrate and defining between them a channel region, one of the source region and the drain region being coupled with the I/O pad, the other one of the source region and the drain region being coupled with the Vdd terminal;
an impurity implantation region of impurities of a second conductive-type formed in a first sector of the channel region, the first sector reaching at most one of the source region and the drain region;
a gate insulating layer on the substrate over at least a portion of the impurity implantation region and over at least a portion of an area adjacent the impurity implantation region; and
a gate on the gate insulating layer over at least a portion of the first sector and over at least a portion of a region adjacent to the first sector.

6. The transistor of claim 5, wherein the first sector has a narrower line width than a line width of the gate.

7. The transistor of claim 5, wherein the gate is over a first portion of the first sector and over a second portion of an area adjacent the first sector, and wherein the first portion is in a predetermined ratio with the second portion.

8. The transistor of claim 5, wherein the first sector does not reach either one of the source region and the drain region.

9. The transistor of claim 8, wherein the first sector is separated from the source region and from the drain region by equal distances.
